(19) United States
(12) Patent Application Publication
(10) Pub. No.: US 2024/0203688 A1
(43) Pub. Date: Jun. 20, 2024

(54) APPARATUS AND METHOD FOR FABRICATING SEMICONDUCTOR DEVICE BY USING FOCUSED ION BEAM AND SCANNING ELECTRON MICROSCOPE SUPPORTED BY ELECTRON DIFFRACTION PATTERN

(71) Applicant: SAMSUNG ELECTRONICS CO., LTD., SUWON-SI (KR)

(72) Inventor: Kunsu KIM, SUWON-SI (KR)

(21) Appl. No.: 18/366,322

(22) Filed: Aug. 7, 2023

(30) Foreign Application Priority Data
Dec. 19, 2022 (KR) 10-2022-0178687

(51) Int. Cl. H01J 37/244; H01J 37/147; H01J 37/20; H01J 37/28

(52) U.S. Cl. CPC H01J 37/244; H01J 37/1478; H01J 37/20; H01J 37/28; H01J 2237/221; H01J 2237/24475; H01J 2237/2817

(57) ABSTRACT

An apparatus for manufacturing semiconductor devices is disclosed. The apparatus includes an electron gun configured to generate an input electron beam and irradiate a sample with the input electron beam, an ion beam device configured to generate an ion beam and irradiate the sample with the ion beam, and a detector configured to detect emitted electrons from the sample. The detector includes an electron backscatter diffraction detector and detects the emitted electrons simultaneously when the sample is irradiated by the ion beam.

### CROSS-REFERENCE TO RELATED APPLICATION

This application claims priority under 35 U.S.C. § 119 to Korean Patent Application No. 10-2022-0178687, filed on Dec. 19, 2022 in the Korean Intellectual Property Office, the disclosure of which is incorporated by reference herein in its entirety.

### FIELD

The present disclosure relates to an apparatus and a method for fabricating a semiconductor device by using an electron microscope and an ion beam based on a diffraction pattern.

### DISCUSSION

The electron beam of a scanning electron microscope (SEM) apparatus, for example, may react with a sample to provide topographical information about the surface shape of a sample, morphological information such as the shape and size of the particles constituting the sample, and crystallographic information such as the arrangement of atoms in the sample. This information may be analyzed by a detector.

A SEM apparatus enables the observation of microstructures that cannot be optically observed due to resolution limitations of optical microscopes. SEMs have been used in a wide range of fields such as medicine, biotechnology, biology, microorganisms, materials engineering, and food engineering.

A focused ion beam (FIB) apparatus is a device that detects secondary ions generated by an ion beam scanning the surface of a sample. A FIB may be used to observe an image of a sample and/or process a surface of the sample.

### SUMMARY

The present disclosure provides an apparatus and a method for manufacturing a semiconductor device by using a scanning electron microscope (SEM) and a focused ion beam (FIB) with high measurement sensitivity.

According to an embodiment of the present disclosure, there is provided an apparatus for manufacturing semiconductor devices including an electron gun configured to generate an input electron beam and irradiate the sample with the input electron beam, an ion beam device configured to generate an ion beam and irradiate the sample with the ion beam, and a detector configured to detect emitted electrons from the sample. The detector may include an electron backscatter diffraction detector and may detect the emitted electrons simultaneously when the sample is irradiated by the ion beam.

According to an embodiment of the present disclosure, there is provided an apparatus for manufacturing a semiconductor device including an SEM configured to generate an input electron beam and irradiate the sample with the input electron beam, and including a detector configured to detect emitted electrons from the sample by the input electron beam, an ion beam device configured to generate an ion beam and irradiate the sample with the ion beam, a stage configured to support and rotate the sample, and a processor configured to control the stage based on information obtained from the detector. The detector may include an electron backscatter diffraction detector and may detect the emitted electrons simultaneously when the sample is irradiated by the ion beam.

According to an embodiment of the present disclosure, there is provided a method of manufacturing a semiconductor device by using a semiconductor manufacturing apparatus. The method including capturing an image of a sample, measuring an orientation of the sample, and comparing a current orientation value from the sample with a target orientation value. The semiconductor manufacturing apparatus includes an SEM configured to generate an input electron beam and irradiate the sample with the input electron beam, and including a detector configured to detect emitted electrons from the sample, an ion beam device configured to generate an ion beam and irradiate the sample with the ion beam, a stage configured to support and rotate the sample, and a processor configured to control the stage based on information obtained from the detector. The detector may include an electron backscatter diffraction detector, and the detector may be configured to detect the emitted electrons simultaneously when the sample is irradiated by the ion beam.

### BRIEF DESCRIPTION OF THE DRAWINGS

Embodiments of the present disclosure will be more clearly understood from the following detailed description when taken in conjunction with the accompanying drawings, in which:

FIG. 1 is a schematic diagram illustrating an apparatus for manufacturing a semiconductor device, according to an embodiment;

FIG. 2 is a block diagram showing a configuration of a processor, according to an embodiment;

FIG. 3 is a plan view diagram illustrating a configuration of a wafer, according to an embodiment;

FIG. 4 is a cross-sectional view diagram illustrating a configuration of a sample, according to an embodiment;

FIG. 5 is a flowchart diagram showing a method of manufacturing a semiconductor device, according to an embodiment;

FIG. 6 is a flowchart diagram showing a method of comparing an orientation value from the sample with a target orientation value, according to an embodiment;

FIGS. 7A to 7C are conceptual diagrams specifically illustrating a method of manufacturing a semiconductor device, according to an embodiment;

FIG. 8 is a schematic diagram illustrating a semiconductor module including the semiconductor device, according to an embodiment;

FIG. 9 is a schematic diagram illustrating a semiconductor module including a semiconductor device, according to an embodiment;

FIG. 10 is a block diagram showing an electronic system including the semiconductor device, according to an embodiment;

FIG. 11 is a block diagram schematically showing another electronic system including the semiconductor device, according to an embodiment; and

FIG. 12 is perspective view diagram schematically illustrating a mobile wireless phone including the semiconductor device, according to an embodiment.

### DETAILED DESCRIPTION

Hereinafter, illustrative embodiments of the present disclosure will be described in detail with reference to the accompanying drawings. The same or like reference numerals may be used to denote the same or like elements in the drawings, and substantially duplicate description of the same or like elements may be omitted.

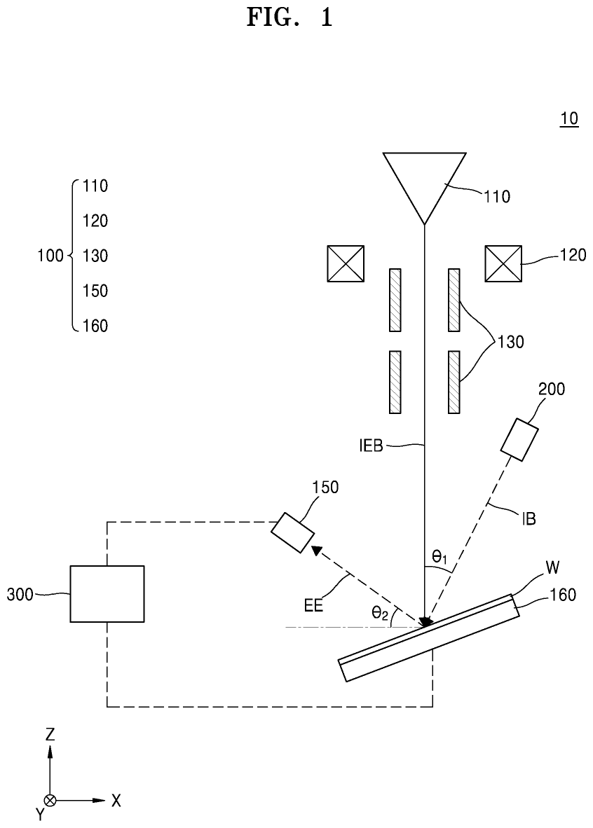

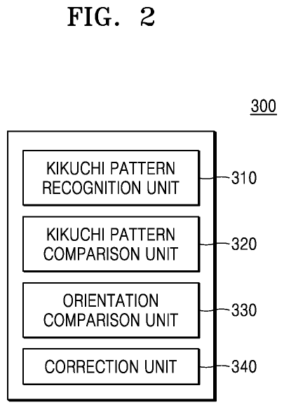

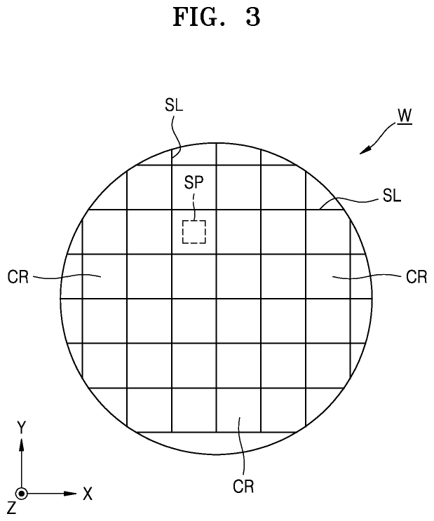

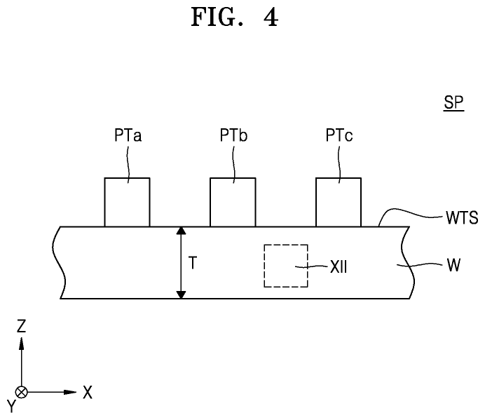

FIG. 1 illustrates an apparatus for manufacturing a semiconductor device according to an embodiment. FIG. 2 shows a configuration of a processor according to an embodiment. FIG. 3 illustrates a configuration of a wafer according to an embodiment. FIG. 4 illustrates a configuration of a sample according to an embodiment.

Referring to FIGS. 1 through 4, a semiconductor manufacturing apparatus 10 for manufacturing a semiconductor device may include a scanning electron microscope (SEM) 100, an ion beam device 200, and a processor 300. The semiconductor device may be manufactured by the ion beam device 200, and the orientation information of the semiconductor device may be obtained by the SEM 100 of the semiconductor manufacturing apparatus 10. When the semiconductor device is manufactured by the ion beam device 200 in the semiconductor manufacturing apparatus 10, the SEM 100 may obtain orientation information of the semiconductor device in a state that a stage 160 is fixed.

The SEM 100 may be configured to measure a wafer W. According to embodiments, the SEM 100 may measure by scanning the wafer W on which the manufacturing process of the semiconductor device is performed. In an embodiment, the SEM 100 may measure the wafer W and obtain topographical information about the wafer W, morphological information such as the shape and size of particles of the wafer W, and crystallographic information such as the arrangement of atoms in the wafer W.

In an embodiment, an input electron beam (IEB) may irradiate the wafer W. Electrons, which are generated by interactions between the input electron beam IEB and the wafer W in the SEM 100, may be emitted as emitted electrons EE; and thus, the SEM 100 may evaluate a previous manufacturing process of the semiconductor device by using the emitted electrons EE. The emitted electrons EE may be generated by elastic scattering and/or inelastic scattering. In an embodiment, the emitted electrons EE generated by elastic scattering may be considered.

Such elastic scattering is a phenomenon in which electrons in the input electron beam IEB are reflected in a direction substantially different (e.g., opposite) to an input direction of the input electron beam IEB without a substantial change in energy of the electrons in the input electron beam IEB by the potential of the atomic nuclei of the wafer W. The electrons escaping from the surface of the wafer W by elastic scattering are called back-scattered electrons, and the back-scattered electrons may have energy of about 50 eV or more. The back-scattered electrons may provide information about a structure and a composition near the surface of the wafer W.

In addition, the SEM 100 may further detect signals caused by incoherent elastic scattering, transmitted electrons, cathodoluminescence, or the like.

The SEM 100 may include an electron gun 110, a focusing lens 120, a deflector 130, a detector 150, and the stage 160, without limitation thereto.

The electron gun 110 may generate and emit the input electron beam IEB. The wavelength of the input electron beam IEB may be determined by the energy of electrons emitted from the electron gun 110. In an embodiment, the wavelength of the input electron beam IEB may be a few nanometers. In an embodiment, the electron gun 110 may be any one of a cold field emission (CFE) type, a Schottky emission (SE) type, or a thermionic emission (TE) type.

The electron gun 110 may generate the input electron beam IEB by thermally and/or electrically applying energy to electrons of a solid source material, which may act as an electron source, with energy greater than a work function (e.g., the difference between the energy level in a vacuum and the Fermi energy level).

The focusing lens 120 may be positioned on a path of the input electron beam IEB between the electron gun 110 and the wafer W. In an embodiment, the focusing lens 120 may focus the input electron beam IEB onto the deflector 130. Accordingly, the controllability of the input electron beam IEB by the deflector 130 may be optimized.

The deflector 130 may be positioned on a path of the input electron beam IEB between the focusing lens 120 and the wafer W. The deflector 130 may deflect the input electron beam IEB emitted from the electron gun 110. The deflector 130 may deflect the input electron beam IEB so that the input electron beam IEB passes through the focusing lens 120 and an objective lens to irradiate a set position on the wafer W. In an embodiment, the deflector 130 may control the input electron beam IEB to scan the wafer W. The deflector 130 may be one of an electric type or a magnetic type.

The objective lens may be positioned on a path of the input electron beam IEB between the deflector 130 and the wafer W. The objective lens may focus the input electron beam IEB onto the wafer W. As the input electron beam IEB irradiates a relatively narrow area on the wafer W, the resolution of the SEM 100 may be optimized.

The irradiating system of the input electron beam IEB is described above to include the focusing lens 120 and the deflector 130, but those are illustrative non-limiting examples and embodiments are not limited thereto. Those of ordinary skill in the pertinent art may easily understand various modifications to the transmitting system of the input electron beam IEB in which a different or additional focusing lens and/or a different and/or additional deflector are included based on the description herein.

The detector 150 may detect at least a portion of the emitted electrons EE emitted from the wafer W. The detector 150 may detect an electron diffraction pattern of the emitted electrons EE. For example, the detector 150 may detect the back-scattered electrons. The detector 150 may include an electron back-scatter diffraction (EBSD) detector, without limitation thereto.

The detector 150 may detect a Kikuchi pattern inside a sample SP. For example, the detector 150 may detect emitted electrons EE from the sample SP that were substantially delivered to the sample SP by the input electron beam IEB. The Kikuchi pattern refers to a phenomenon occurring when the input electron beam IEB incident upon the sample SP reacts with the crystal of the sample SP in an elastic collision and/or an inelastic collision, to thereby generate diffraction. The emitted electrons EE are scattered in substantially all directions inside the sample SP, and the emitted electrons EE scattered backwards may be detected by the detector 150 even if they do not pass through the sample SP. The detected emitted electrons EE may provide information about the arrangement orientation of the crystal lattice of the sample SP such as by Bragg's law. For example, the emitted electrons EE may provide information about the arrangement orientation of the crystal lattice of the wafer W. Accordingly, the crystal orientation of the sample SP and/or of the wafer W may be analyzed by the SEM 100.

The stage 160 may support the wafer W that is to be measured. The stage 160 may move the wafer W in a horizontal direction (e.g., along an X-axis and/or a Y-axis) and/or a vertical direction (e.g., along a Z-axis), or rotate the wafer W with respect to the vertical direction (e.g., about the Z-axis) such as to align the wafer W with an optical system. For example, the wafer W may be aligned with an optical system including the electron gun 110, the focusing lens 120, the deflector 130 and the objective lens, such as for transmitting the input electron beam IEB.

In an embodiment, a vertical direction (e.g., along a Z-axis) may be parallel to a direction in which the input electron beam IEB of the SEM 100 passes, and a horizontal direction (e.g., along an X-axis and/or a Y-axis) may be a direction substantially perpendicular to the vertical direction (e.g., the Z-axis).

The ion beam device 200 may include an ion source and an ion concentration optical system, without limitation thereto. The ion beam device 200 may generate an ion beam IB from the ion source and emit the ion beam IB. For example, the ion beam device 200 may generate ions such as protons, helium, nitrogen, argon, and/or xenon. For example, the ion beam device 200 may include a focused ion beam (FIB).

For example, the ion beam device 200 may focus the ion beam IB on the sample SP, detect ions and/or electrons emitted from the sample SP, and take an image of the sample SP. The ions and/or electrons emitted from the sample SP may be referred to as secondary ions and/or secondary electrons, respectively. Where the ion beam IB is a focused ion beam FIB, taking an image of the sample by using the secondary ions and/or the secondary electrons may be referred to as FIB imaging.

For example, the ion beam device 200 may accelerate the generated ion beam IB by using a magnetic field and/or an electric field and irradiate the accelerated ion beam IB onto a selected area of the sample SP, and thus, the sample SP may be processed by the ion beam IB. Where the ion beam IB is a focused ion beam FIB, processing the selected area of the sample SP by the accelerated ion beam may be referred to as FIB milling.

For example, the ion beam device 200 may perform etching on the surface of the sample SP and decompose the precursor gas into volatile components and nonvolatile components when the surface of the sample SP is etched. Nonvolatile materials may remain on the surface of the sample SP and/or may be deposited on the surface of the sample SP. Where the ion beam IB is a focused ion beam FIB, deposition of the nonvolatile materials on the sample SP in the etching process may be referred to as FIB deposition.

The ion beam device 200 may irradiate the sample SP with the ion beam IB. For example, the ion beam device 200 may etch at least a portion of the sample SP. For example, the ion beam device 200 may etch at least one of one or more material layer patterns PTa, PTb, and/or PTc of the sample SP.

The wafer W may include one or more chip regions CR separated along at least one scribe line SL. The chip region CR may be a region in which a semiconductor device is formed. The plurality of material layer patterns PTa, PTb, and PTc may be arranged on the wafer W. The material layer patterns PTa, PTb, and/or PTc may include various layer patterns such as a photoresist pattern or a conductive pattern providing a passage for an electrical signal, or an insulating pattern for insulating neighboring conductive patterns from each other, or the like.

The wafer W and the plurality of material layer patterns PTa, PTb, and PTc may be included in the sample SP. For example, the detector 150 may obtain orientation information about the sample SP from the wafer W. For example, a thickness T of the wafer W in the vertical direction (e.g., the Z axis) may be at least about 100 nm or more. Where the thickness T of the wafer W is more than about 100 nm, the detector 150 may easily obtain the orientation information for the sample SP from the wafer W.

The wafer W may include, for example, a semiconductor substrate. The wafer W may be, for example, a single crystal substrate. The semiconductor substrate may include silicon (Si), strained silicon (e.g., a layer of silicon strained over a substrate of silicon germanium), a silicon alloy, silicon carbide (SiC), silicon germanium (SiGe), silicon germanium carbide (SiGeC), germanium (Ge), a germanium alloy, gallium arsenide (GaAs), indium arsenide (InAs), and/or one of a Group III-V compound semiconductor and/or a Group II-VI compound semiconductor, a combination thereof, and/or a stack thereof. The wafer W may be positioned on the stage 160.

The single crystal material has a regular crystal lattice and a constant crystal orientation. Thus, when the wafer W includes a single crystal material, the detector 150 may easily obtain the orientation information of the wafer W from the electron diffraction pattern of the wafer W. At least a portion of the material layer patterns PTa, PTb, and PTc of the sample SP may be etched away, so that the detector 150 obtains the orientation information of the wafer W. Accordingly, at least a portion of an upper surface WTS of the wafer W may be exposed. At least a portion of the input electron beam IEB may be incident along the upper surface WTS of the exposed wafer W.

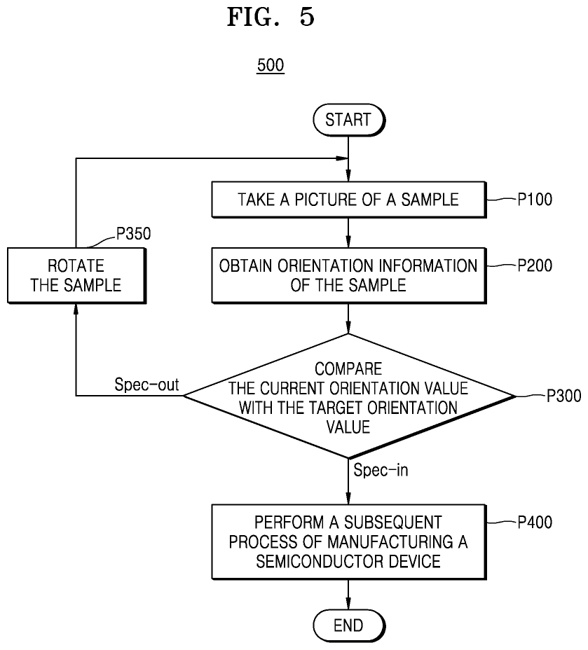

The processor 300 may include a Kikuchi pattern recognition unit 310, a Kikuchi pattern comparison unit 320, an orientation comparison unit 330, and a correction unit 340. The processor 300 may process an image generated by the detector 150. The processor 300 may process the image by using the Kikuchi pattern recognition unit 310, the Kikuchi pattern comparison unit 320, the orientation comparison unit 330, and the correction unit 340, and a method of processing the image by the processor 300 is described in detail with reference to FIGS. 5 to 7C. In an embodiment, the semiconductor manufacturing apparatus 10 may further include a controller configured to control each optical element of the SEM 100. The controller may generate, for example, a signal for controlling the oscillation of the electron gun 110, the operation of the focusing lens 120, the operation of the deflector 130, and/or the operation of the objective lens.

Although FIG. 2 illustrates that the Kikuchi pattern recognition unit 310, the Kikuchi pattern comparison unit 320, the orientation comparison unit 330, and the correction unit 340 are different and separate elements, at least two of the Kikuchi pattern recognition unit 310, the Kikuchi pattern comparison unit 320, and the correction unit 340 may achieve the purposes thereof by a single common element. In another embodiment, at least one of the Kikuchi pattern recognition unit 310, the Kikuchi pattern comparison unit 320, the orientation comparison unit 330, and the correction unit 340 may include one or more elements.

The controller and the processor 300 may include a computing device, such as a workstation computer, a desktop computer, a laptop computer, and/or a tablet computer. The controller and the processor 300 may be configured with separate hardware, respectively, or may be separate software included in shared hardware. The controller and the processor 300 may include a simple controller, a microprocessor, a complex processor such as a central processing unit (CPU), a graphics processing unit (GPU) or the like, a processor configured by software, dedicated hardware and/or dedicated firmware. The controller and the processor 300 may be implemented by general-purpose computers or application-specific hardware, such as a digital signal processor (DSP), a field programmable gate array (FPGA), and/or an application specific integrated circuit (ASIC).

In an embodiment, the operation of the controller and the processor 300 may be performed by instructions stored in a machine-readable medium that may be read and executed by one or more processors. For example, the machine-readable medium may include any mechanism for storing and/or transmitting information in a form readable by a machine (e.g., a computing device). For example, the machine-readable medium may include read-only memory (ROM), random-access memory (RAM), magnetic disk storage media, optical storage medium, flash memory, electrical, optical, acoustic, or other forms of radio signals (e.g., carrier waves, infrared signals, digital signals, or the like) and other signals.

The controller and the processor 300 may include firmware, software, routines, and/or instructions for performing the operations that are described for the controller and the processor 300 and/or any process described below. However, this is for convenience of description, and it should be understood that the operation of the controller and the processor 300 described above may be performed by computing devices, processors, controllers, or other devices for executing firmware, software, routines, instructions, or the like.

To obtain the orientation information from the sample SP in manufacturing the semiconductor device by the semiconductor manufacturing apparatus 10, the input electron beam IEB and the ion beam IB may be set to form a first angle (θ₁), and the emitted electrons EE and the horizontal plane may be set to form a second angle (θ₂). The first angle (θ₁) may be, for example, about 45 degrees to about 55 degrees, and the second angle (θ₂) may be, for example, about 15 degrees to about 25 degrees. In another embodiment, the first angle (θ₁) may be, for example, about 80 degrees to about 90 degrees, and the second angle (θ₂) may be, for example, about −10 degrees to about −20 degrees.

In a comparative semiconductor manufacturing apparatus, an SEM that does not include a detector for detecting electron backscatter diffraction, or the like, may be unable to obtain orientation information of a wafer. Moreover, such a comparative semiconductor manufacturing apparatus may have difficulties in obtaining orientation information of a sample and/or in etching the sample with a comparative ion beam device. In addition, the orientation information may generally be obtained from an outer surface of the sample in such a comparative semiconductor manufacturing apparatus, but it may be difficult to obtain accurate orientation information because various materials may be mixed on the surface of the sample.

In contrast, in the semiconductor manufacturing apparatus 10 according to an embodiment, the SEM 100 includes an electron backscatter diffraction (EBSD) detector 150, so that the orientation information from the sample SP may be obtained. In addition, in the semiconductor manufacturing apparatus 10 according to an embodiment, the input electron beam IEB and the ion beam IB may be arranged at the first angle (θ₁), and the emitted electron EE and the horizontal plane may be arranged at the second angle (θ₂), so that the orientation information from the sample SP may be obtained in performing the process for the sample SP by using the ion beam device 200. Moreover, the semiconductor manufacturing apparatus 10 according to an embodiment may capture images of the Kikuchi pattern of the wafer W from the upper surface WTS that is exposed by removing at least some of the material layer patterns PTa, PTb, and PTc from the sample SP. Since the wafer W includes a single crystal material, the semiconductor manufacturing apparatus 10 may obtain accurate orientation information from the sample SP. In addition, the semiconductor manufacturing apparatus 10 may manufacture a semiconductor device under optimized conditions by utilizing characteristics where the physical properties of the wafer W vary depending on the orientation information. Therefore, according to the semiconductor manufacturing apparatus 10, at least some of the material layer patterns PTa, PTb, and PTc of the sample SP may be removed according to the orientation information, and thus, a certain pattern may be exposed to the ion beam IB of the ion beam device 200. The semiconductor manufacturing apparatus 10 may check the uniformity of the semiconductor device from the shape and/or the thickness of the semiconductor device by using the SEM 100 and/or a transmission electron microscope (TEM).

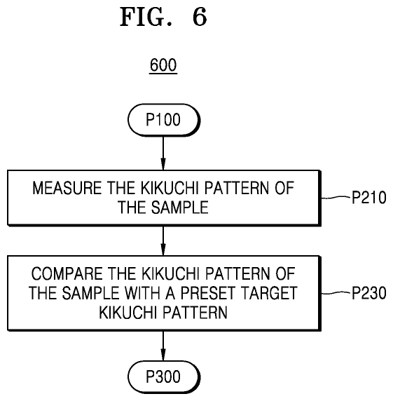

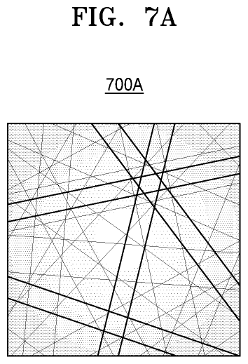

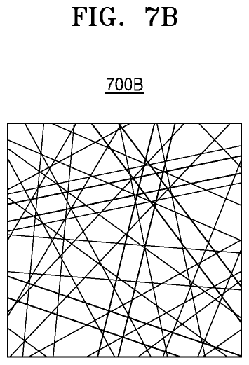

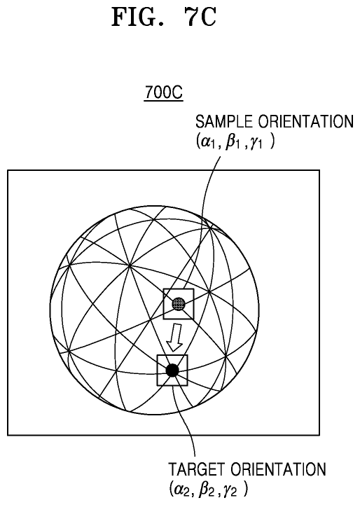

FIG. 5 shows a method of manufacturing a semiconductor device, according to an embodiment. FIG. 6 shows a method of comparing an orientation value from the sample with a target orientation value, according to an embodiment. FIGS. 7A to 7C illustrate a method of manufacturing a semiconductor device, according to an embodiment. In particular, FIGS. 7A to 7C illustrate the Kikuchi pattern and the orientation information formed by interacting with an electron beam at a portion “XII” of the wafer W shown in FIG. 4. The descriptions with reference to FIGS. 5 to 7C are presented together with reference to FIGS. 1 to 4.

Referring to FIGS. 5 and 7A, in operation P100, the detector 150 may capture an image an image of the sample SP. For example, the detector 150 may capture an image an image of the wafer W including the sample SP. The detector 150 may capture an image an image of the wafer W using an EBSD method, without limitation thereto.

Referring to FIGS. 5, 6, and 7B, in operation P200, the processor 300 may obtain the orientation information from the sample SP. At first, in operation 210, the Kikuchi line recognition unit 310 may measure the Kikuchi line of the image of the sample SP from the image from the sample SP by using the images from the sample SP that are taken by the detector 150. For example, the Kikuchi line recognition unit 310 may measure the Kikuchi line of the image of the wafer W from the image of the wafer W by using the images of the wafer W or the sample SP that are taken by the detector 150. Then, in operation P230, the Kikuchi pattern comparison unit 320 may compare the Kikuchi line from the sample SP with a preset target Kikuchi line. For example, the Kikuchi pattern comparison unit 320 may compare the Kikuchi line from the sample SP with the preset target Kikuchi line by the similarity analysis method.

Referring to FIGS. 2, 5 and 7C, in operation P300, the processor 300 may compare the current orientation information from the sample SP with the target orientation information. For example, the orientation comparison unit 330 may compare the orientation information from the sample SP with the target orientation information. The orientation information may be expressed as, for example, a combination of alpha (α), beta (β), and gamma (γ), in which the alpha (α) is a rotation axis with respect to the vertical direction (e.g., a Z-axis), the beta (β) is a rotation axis with respect to a first horizonal direction (e.g., an X-axis), and the gamma (γ) is a rotation axis with respect to a second horizontal direction (e.g., a Y-axis).

For example, the orientation comparison unit 330 may compare the first orientation (α₁, β₁, γ₁), which is the current orientation from the sample SP, with the second orientation (α₂, β₂, γ₂) which is the target orientation. In operation 400, a process of manufacturing the semiconductor device may be performed when the difference between the first orientation and the second orientation is within process specifications (Spec-in).

For example, the process of manufacturing the semiconductor device may include a process of etching at least one of the material layer patterns PTa, PTb, and PTc by using the ion beam device 200. For example, the process of manufacturing the semiconductor device may include a deposition process, an etching process, an ion process, a cleaning process, or the like. In addition, the process of manufacturing the semiconductor device may include a test process for the semiconductor device at the wafer W level. Moreover, the process of manufacturing the semiconductor device may include a process of dicing the wafer W into semiconductor chips and a process of packaging the semiconductor chips.

In operation P350, when the difference between the first orientation (α₁, β₁, γ₁) and the second orientation (α₂, β₂, γ₂) is out of the process specifications (Spec-out), the processor 300 may select rotation of the sample SP. The correction unit 340 may rotate the sample SP. The correction unit 340 may control the rotation of the stage 160 to rotate the sample SP, without limitation thereto. For example, the correction unit 340 may rotate the sample SP by the difference between the second orientation (α₂, β₂, γ₂) and the first orientation (α₁, β₁, γ₁). After rotating the sample SP, the processor 300 may repeat operations P100 to P300. For example, operations P100 to P300 may be performed multiple times.

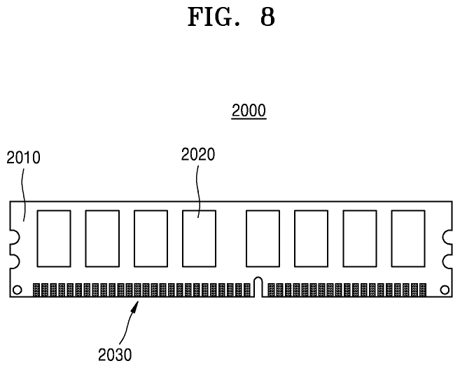

FIG. 8 illustrates a semiconductor module including the semiconductor device, according to an embodiment.

Referring to FIG. 8, a semiconductor module 2000 may include a memory module including a memory device. The semiconductor module 2000 may include a module substrate 2010, one or more semiconductor devices 2020 positioned on the module substrate 2010, and one or more terminals 2030. The terminals 2030 may include a conductive metal. The terminals 2030 may be electrically connected to the semiconductor devices 2020. The module substrate 2010 may be a memory module substrate. The module substrate 2010 may include a printed circuit board (PCB) or a wafer, without limitation thereto.

The semiconductor devices 2020 may include memory devices, such as dynamic random-access memory (DRAM) devices, without limitation thereto. The semiconductor devices 2020 may include the semiconductor devices and semiconductor packages including the semiconductor devices, according to an embodiment.

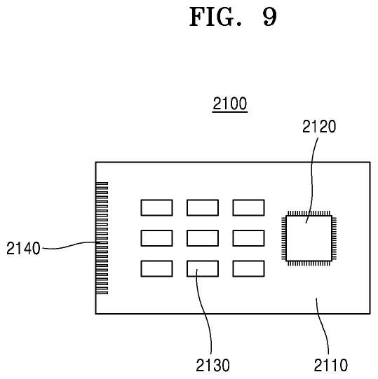

FIG. 9 illustrates a semiconductor module including a semiconductor device, according to an embodiment.

Referring to FIG. 9, a semiconductor module 2100 may include a memory device 2130 on a module substrate 2110. The memory device 2130 may include a memory such as a NAND flash memory. The semiconductor module 2100 may include a semiconductor device 2120 mounted on the module substrate 2110. Input/output terminals 2140 may be positioned on at least one side of the module substrate 2110.

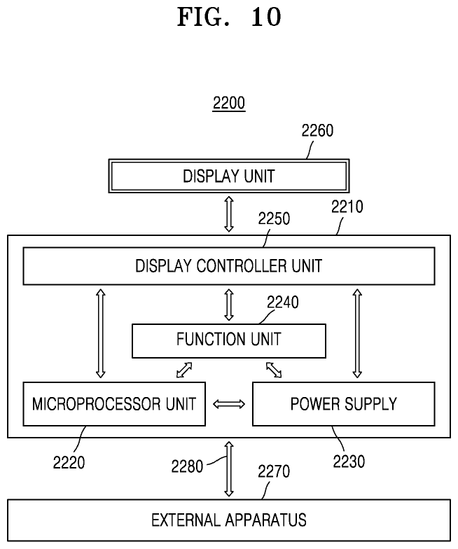

FIG. 10 shows an electronic system including the semiconductor device, according to an embodiment.

Referring to FIG. 10, an electronic system 2200 may include a body 2210. The body 2210 may include a microprocessor unit 2220, a power supply 2230, a function unit 2240, and/or a display controller unit 2250. The body 2210 may include a system board and/or a mother board.

The microprocessor unit 2220, the power supply 2230, the function unit 2240, and the display controller unit 2250 may be mounted or installed on the body 2210. A display unit 2260 may be positioned on the upper surface of the body 2210 or positioned outside the body 2210. For example, the display unit 2260 may be positioned on the surface of the body 2210 to display an image processed by the display controller unit 2250. The power supply 2230 may receive a certain voltage from an external power source, or the like, divide the voltage into various voltage levels, and supply the divided voltages to the microprocessor unit 2220, the function unit 2240, the display controller unit 2250, and the like. The microprocessor unit 2220 may receive a voltage from the power supply 2230 and control the function unit 2240 and the display unit 2260.

The function unit 2240 may perform various functions of the electronic system 2200. For example, when the electronic system 2200 is a mobile electronic product such as a mobile phone, the function unit 2240 may include various components for performing a wireless communications function such as an image output to the display unit 2260, a voice output to a speaker, or the like, by dialing or communicating with external apparatuses, and may function as an image processor when the electronic system 2200 includes a camera.

In an embodiment, when the electronic system 2200 is connected to a memory card or the like for increasing memory size, the function unit 2240 may include a memory card controller. The function unit 2240 may transmit and receive signals to and from an external device by a wired or wireless communications unit.

In addition, when the electronic system 2200 uses a universal serial bus (USB) for function expansion, the function unit 2240 may function as an interface controller.

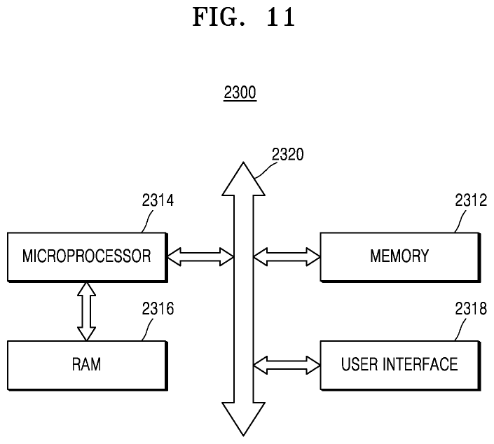

FIG. 11 shows another electronic system including the semiconductor device, according to an embodiment.

Referring to FIG. 11, an electronic system 2300 may include a semiconductor device according to an embodiment. The electronic system 2300 may be used for manufacturing a mobile device, a computer, or the like. For example, the electronic system 2300 may include a user interface 2318 for performing data communications, a memory 2312 for storing data, a microprocessor 2314, a RAM 2316, and a bus 2320. The microprocessor 2314 may execute program instructions for the electronic system 2300 and control the electronic system 2300. The RAM 2316 may be used as an operating memory of the microprocessor 2314. The microprocessor 2314, the RAM 2316, and/or other elements may be assembled in a single package. The memory 2312 may include a semiconductor device according to an embodiment, or a semiconductor package including the semiconductor device.

The user interface 2318 may be used to input data to the electronic system 2300 or output data from the electronic system 2300. The memory system 2312 may store various codes for operating the microprocessor 2314, data processed by the microprocessor 2314, and/or external input data. The memory 2312 may be a memory system that includes a controller and a memory.

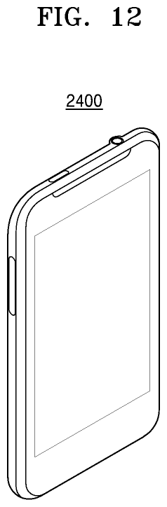

FIG. 12 illustrates a mobile wireless phone including a semiconductor device, according to an embodiment.

Referring to FIG. 12, a mobile wireless phone 2400 may include a semiconductor device according to an embodiment. The mobile wireless phone 2400 may include a tablet PC. Moreover, the semiconductor device according to an embodiment may be used in portable computers such as a laptop computer, mpeg-1 audio layer 3 (MP3) players, MP4 players, navigation devices, solid state disks (SSDs), desktop computers, cars, and home appliances in addition to the tablet PCs.

Although the inventive concept has been described in detail by way of example with reference to illustrative embodiments, the inventive concept is not limited to the above-described embodiments. Various modifications and changes may be made by those of ordinary skill in the pertinent art without departing from the technical spirit and scope of the present disclosure. It should be noted that the embodiments described above are illustrative and not limited in any respects. Therefore, the true scope of technical protection for the inventive concept should be determined by the full scope of the elements recited in the appended claims.

What is claimed is:

1. An apparatus for manufacturing a semiconductor device, the apparatus comprising:
an electron gun configured to generate an input electron beam and irradiate a sample with the input electron beam;
an ion beam device configured to generate an ion beam and irradiate the sample with the ion beam; and
a detector configured to detect emitted electrons from the sample,
wherein the detector includes an electron backscatter diffraction detector, and
wherein the detector detects the emitted electrons simultaneously when the sample is irradiated by the ion beam.

2. The apparatus of claim 1, wherein:
the detector is configured to detect emitted electrons from the sample that were substantially delivered to the sample by the input electron beam,
the sample includes a substrate and a plurality of material layers positioned on the substrate, and
the detector obtains an image of the substrate.

3. The apparatus of claim 2, wherein:
the detector measures a Kikuchi pattern of the substrate.

4. The apparatus of claim 1, further comprising:
a stage configured to support and rotate the sample.

5. The apparatus of claim 1, wherein:
the input electron beam is incident upon the sample in a vertical direction, and
the input electron beam and the ion beam are arranged at a first angle of about 45 degrees to about 55 degrees.

6. The apparatus of claim 1, wherein:
the emitted electrons and a horizontal direction, which is perpendicular to a vertical direction in parallel with an incident direction of the input electron beam, are arranged at a second angle of about 15 degrees to about 25 degrees.

7. An apparatus for manufacturing a semiconductor device, the apparatus comprising:
a scanning electron microscope configured to generate an input electron beam and irradiate a sample with the input electron beam, and including a detector configured to detect emitted electrons from the sample;
an ion beam device configured to generate an ion beam and irradiate the sample with the ion beam;
a stage configured to support and rotate the sample; and
a processor configured to control the stage based on information obtained from the detector,
wherein the detector includes an electron backscatter diffraction detector, and
wherein the detector is configured to detect the emitted electrons simultaneously when the sample is irradiated with the ion beam.

8. The apparatus of claim 7, wherein:
the processor includes a Kikuchi pattern recognition unit, a Kikuchi pattern comparison unit, an orientation comparison unit, and a correction unit.

9. The apparatus of claim 7, wherein:
the processor recognizes the Kikuchi pattern from an image of the sample captured by the detector.

10. The apparatus of claim 9, wherein:
the processor compares the recognized Kikuchi pattern with a preset Kikuchi pattern.

11. The apparatus of claim 10, wherein:
the processor compares the orientation information from the sample with target orientation information.

12. The apparatus of claim 11, wherein:
the processor is configured to control the stage based on the orientation information from the sample and the target orientation information.

13. A method of manufacturing a semiconductor device by using a semiconductor manufacturing apparatus, the method comprising:
capturing an image of a sample;
measuring an orientation from the sample; and
comparing a current orientation value from the sample with a target orientation value,
wherein the semiconductor manufacturing apparatus includes:
a scanning electron microscope configured to generate an input electron beam and irradiate the sample with the input electron beam, and including a detector configured to detect emitted electrons from the sample;
an ion beam device configured to generate an ion beam and irradiate the sample with the ion beam;
a stage configured to support and rotate the sample; and
a processor configured to control the stage based on information obtained from the detector,
wherein the detector includes an electron backscatter diffraction detector, and
wherein the detector is configured to detect the emitted electrons simultaneously when the sample is irradiated by the ion beam.

14. The method of claim 13, wherein:
the detector is configured to detect emitted electrons from the sample that were substantially delivered to the sample by the input electron beam,
when the difference between a current orientation value from the sample and a target orientation value is out of process specifications (Spec-out), the processor rotates the sample.

15. The method of claim 13, wherein:
the sample includes a substrate and a plurality of material layers positioned on the substrate, and
the measuring of the pattern from the sample includes measuring the pattern of the substrate.

16. The method of claim 15, wherein:
the substrate includes a single crystal material.

17. The method of claim 15, wherein:
the substrate has a thickness of 100 nm or more in a vertical direction.

18. The method of claim 15, wherein:
at least a portion of an upper surface of the substrate is exposed.

19. The method of claim 13, wherein:
the measuring of the orientation from the sample includes:
measuring a Kikuchi pattern from the sample; and
comparing the Kikuchi pattern from the sample with a preset target Kikuchi pattern.

20. The method of claim 13, wherein:
the input electron beam and the ion beam are arranged at a first angle,
the emitted electrons and a horizontal direction, which is perpendicular to a vertical direction in parallel with an incident direction of the input electron beam, are arranged at a second angle,
the sum of the first angle and the second angle is between about 60 degrees and about 80 degrees.
